(19) United States
(12) Patent Application Publication
(10) Pub. No.: US 2025/0289712 A1
(43) Pub. Date: Sep. 18, 2025

(54) SYSTEMS AND METHODS FOR ESD PROTECTION OF SEMICONDUCTOR DEVICES

(71) Applicant: Nanusens SL, Cerdanyola del Vallès (ES)

(72) Inventor: Josep MONTANYÀ I SILVESTRE, Cerdanyola del Vallès (ES)

(73) Assignee: Nanusens SL, Cerdanyola del Vallès (ES)

(21) Appl. No.: 19/078,097

(22) Filed: Mar. 12, 2025

Related U.S. Application Data
(60) Provisional application No. 63/564,391, filed on Mar. 12, 2024.

(51) Int. Cl. B81B 7/00; H01L 23/60

(52) U.S. Cl. CPC B81B 7/0064; H01L 23/60; B81B 2207/11

(57) ABSTRACT

An electrostatically-protected integrated circuit (IC) includes a pad configured to provide an electrical connection to outside of the IC. The IC also includes an electrostatic discharge (ESD) device that is electrically connected to the pad and includes a first gap configured to discharge an excessive voltage. A microelectromechanical (MEMS) device is further included that includes a second gap between at least two elements of the MEMS device such that a size of the first gap is less than a size of the second gap.

### CROSS-REFERENCE TO RELATED APPLICATIONS

This application claims priority to and the benefit of U.S. Provisional Application No. 63/564,391, filed on Mar. 12, 2024, and entitled “METHOD AND SYSTEM FOR ESD PROTECTION, THERMIONIC, & OTHER SEMICONDUCTOR DEVICES,” the entire contents of which are incorporated herein by reference.

### TECHNICAL FIELD

The present disclosure relates to semiconductor devices and, more particularly, to ESD protection of semiconductor devices.

### BACKGROUND

ESD (Electrostatic Discharge) in ICs (Integrated Circuits) is the discharge of small amounts of electrical charge that acquire very high voltages and get in touch with the pads of the IC. Despite being a small amount of charge, the very high voltages involved can easily damage the electrical circuit or a MEMS device, resulting in the IC becoming a faulty and no longer operating properly. Hence, there is a need to provide improved ESD protection of ICs, including for MEMS devices.

### SUMMARY

The application, in various implementations, addresses deficiencies associated with existing ICs and/or MEMS-based devices with respect to ESD protection. Moreover, it would be advantageous to use the MEMS inside CMOS technology process to develop new semiconductor devices with improved ESD protection. This application describes illustrative devices and fabrication techniques that enable more robust, resilient, and reliable anti-ESD semiconductor devices and/or MEMS-based devices, while using standard CMOS processing.

Given the small dimensions and gaps, many in the submicron range, of certain MEMS devices, there is a technical problem with ESD, because it is easy for sparks to occur at voltages as low as 300V and even less. This means that for standard human body model (HBM) 1 kV compliance requirements, careful design is needed. In certain implementations, these small gaps are needed to achieve sufficient IC performance. One solution is to prepare another (second) gap, smaller and closer to the ESD input, so that an IC has a controlled gap to discharge a harmful ESD voltage away from the MEMS device. An inventive ESD device as discussed herein will be structurally strong enough and without moving parts, so it will be able to withstand a very large number of sparks without failing.

Typical MEMS-based devices have weak, mobile, and fragile parts that can be destroyed if a spark is generated at the device. In certain implementations, the back-end metal lines of a semiconductor process are used to form the ESD device with a CMOS process and a post-process with vHF. In some implementations, the gap is not filled with SiO₂ but with air, N₂, or another gas inside. Without etching the SiO₂ layer with vHF or another means, this ESD protection may not work because there may be no spark inside the oxide.

The inventive concept can be further expanded, and what could have been seen initially as a problem is, in reality, a technical advantage. Being able to build such small gaps, it allows an IC to generate sparks at relatively low voltages at 100 v and/or while still in the hundreds of volts.

In one aspect, an electrostatically-protected integrated circuit (IC) includes a pad configured to provide an electrical connection to outside of the IC and an electrostatic discharge (ESD) device being electrically connected and/or coupled to the pad. The ESD device includes a first gap configured to discharge an excessive voltage. The IC also includes a microelectromechanical (MEMS) device that is spaced away from the pad. The MEMS device includes a second gap between at least two elements of the MEMS device. The size of the first gap is less than a size of the second gap.

In some implementations, the first gap is sized to generate a spark at a target threshold voltage where the target threshold voltage is set to prevent excessive voltage from reaching and damaging the MEMS device. A shape of a portion of the ESD device may be configured to at least partially determine the target threshold voltage. The shape may be varied vertically and/or horizontally. The size of the first gap may be less than or equal to 300 μm, 30 μm, 3 μm, 300 nm, or less. The target threshold voltage may be less than or equal to 1,000 volts, 400 volts, 350 volts, 325 volts, 315 volts, 250 volts, 200 volts, 150 volts, 125 volts, or 100 volts.

The ESD device may include a switch configured to discharge the excessive voltage when activated. A seal may surround the ESD device. The seal may encapsulate the ESD device in a gas, such as an inert gas including, without limitation, N₂ or Ar. The ESD device may be spaced away from the pad by a first distance and the MEMS device is spaced away from the pad by a second distance, where the first distance is less than the second distance.

In another aspect, an electrostatic discharge (ESD) device includes an electrostatic discharger being coupled electrically to a pad and forming a first gap. The electrostatic discharger may be configured to discharge an excessive voltage received by the pad via the first gap. In some implementations, the size of the first gap determines the target threshold voltage at which the excessive voltage is discharged. The size of the first gap may be less than the size of a second gap formed between at least two elements of a MEMS device. A shape of a portion of the electrostatic discharger may at least partially determine the target threshold voltage. The shape may be varied vertically and/or horizontally. The size of the first gap may be less than or equal to 300 μm.

The target threshold voltage may be less than or equal to one of 1,000 volts, 400 volts, 350 volts, 325 volts, 315 volts, 250 volts, 200 volts, 150 volts, 125 volts, or 100 volts. The ESD device and/or electrostatic discharger may include a switch configured to discharge the excessive voltage when activated. A seal may surround and encapsulate the ESD device in a gas such as an inert gas including, for example, N₂ or Ar.

In a further aspect, a method for manufacturing and/or fabricating an electrostatically-protected integrated circuit (IC) includes: forming a pad configured to provide an electrical connection outside of the IC; forming an electrostatic discharge (ESD) device including an electrical connection with the pad; configuring the ESD device to discharge an excessive voltage including forming a first gap within the ESD device forming a MEMS device at a location spaced away from the pad; forming a second gap within the MEMS device between at least two elements of the MEMS device; and setting a size of the first gap to less than a size of the second gap.

In yet another aspect, an electrostatically-protected IC includes a pad configured to provide an electrical connection to outside of the IC and an ESD device that is spaced away from the pad via a first spacing and configured to discharge an excessive voltage. The IC also includes a MEMS device that is spaced away from the pad via a second spacing where a distance of the first spacing is less than a distance of the second spacing.

In various implementations, there can be three implementation options: 1) ESD device with smaller gap, 2) ESD device that is farther away from the pad, or 3) ESD device with gap reduced with target voltage (via, for example, a bridge, cantilever, switch and/or similar set up). In certain implementations, an ESD device may combine two or all of these options.

A reading of the following detailed description and a review of the associated drawings will make apparent the advantages of these and other structures. Both the foregoing general description and the following detailed description serve as an explanation only and do not restrict aspects of the disclosure as claimed.

### BRIEF DESCRIPTION OF THE DRAWINGS

Reference to the detailed description, combined with the following figures, will make the disclosure more fully understood, wherein:

FIG. 1 shows a perspective view of a CMOS semiconductor pad according to an implementation of the disclosure;

FIG. 2 shows cross-sectional view of a pad according to an implementation of the disclosure;

FIG. 3 shows a graph of breakdown voltage vs. contact gap for a ESD device according to an implementation of the disclosure;

FIG. 4 shows a block diagram of the distance between a pad and ESD device and the pad and a MEMS device according to some implementations of the disclosure;

FIG. 5 shows a layout of a proof of concept integrated circuit including an ESD device according to an implementation of the disclosure;

FIG. 6 shows a graph of breakdown voltage vs. time when a 1 kV across a gap of 300 μm or less of an ESD device according to an implementation of the disclosure; and

FIG. 7 shows a process for manufacturing an IC including an ESD device according to an implementation of the disclosure.

### DETAILED DESCRIPTION

In the following description, like components have the same reference numerals, regardless of different illustrated implementations. To illustrate implementations clearly and concisely, the drawings may not necessarily reflect appropriate scale and may have certain structures shown in somewhat schematic form. The disclosure may describe and/or illustrate structures in one implementation, and in the same way or in a similar way in one or more other implementations, and/or combined with or instead of the structures of the other implementations.

In the specification and claims, for the purposes of describing and defining the invention, the terms “about” and “substantially” represent the inherent degree of uncertainty attributed to any quantitative comparison, value, measurement, or other representation. The terms “about” and “substantially” moreover represent the degree by which a quantitative representation may vary from a stated reference without resulting in a change in the basic function of the subject matter at issue. Open-ended terms, such as “comprise,” “include,” and/or plural forms of each, include the listed parts and can include additional parts not listed, while terms such as “and/or” include one or more of the listed parts and combinations of the listed parts. Use of the terms “top,” “bottom,” “above,” “below” and the like helps only in the clear description of the disclosure and does not limit the structure, positioning and/or operation of the disclosure in any manner.

Certain aspects of the present disclosure describe illustrative devices and fabrication techniques that enable smaller size and lower parasitic capacitance for electrostatic discharge protection of ICs, including ICs with MEMS-based devices. Also, improved linearity (which may not be relevant for digital circuits, but it is for RF devices like the DTC). In certain implementations, very small parasitic capacitance will be added by ESD devices because of the very small dimensions of the ESD devices. Current solid state solutions are very large and add large parasitic capacitance, in addition to the cost, which is proportional to the area in semiconductors. Also, linearity will not be compromised because an ESD device is mechanically fixed such that it will not change with an applied voltage (unless in the case of a closing switch, but this should ideally be closed only once, and even if not, the parasitic capacitance that will be adding should be minimal).

One potential way to increase the total life of an IC and/or ESD device may be to add several devices in parallel. However, this may have a drawback of increasing the parasitic capacitance. In certain implementations, there is one device that sparks first, and the current may not be split evenly between multiple devices. This may limit applicability to situations where there is a need to discharge more current. But, even when higher ESD voltages are applied, the total energy and amount of current will be limited, and hence ESD protection devices should be effective for higher voltages. But for this reason, that is, because the spark will usually happen only in one device, then even if that device is destroyed, the other ESD devices will remain operational. So this makes it possible to build a ESD protection device and/or system that can withstand a finite number of discharges. This is acceptable in many situations, like when the ICs are not exposed to the outside of the system where they are located, and the ESD protection for the IC chip is only needed during assembly and soldering.

A technical advantage of implementing the ESD devices described herein includes smaller parasitic capacitance. This is important when protecting digital lines, as otherwise the ESD protection would likely reduce the transmission bandwidth. It is also important for a radio frequency (RF) digital tunable capacitor (DTC), as otherwise it would reduce the capacitance ratio and the minimum capacitance, which are important parameters. In implementations where an ESD device is integrated into an IC, in addition to the small parasitical capacitance, the ESD device occupies a very small area, which results in very low cost.

These protection devices as described herein can be placed between pads, connecting them, and/or between pads and ground. While both approaches are useful, connecting each pad to ground, and/or searching for the minimal path is a technical solution. In some implementations, an ESD device may connect each pad with ground and/or with the next pad. This avoids alternative paths for a potential ESD discharge to happen.

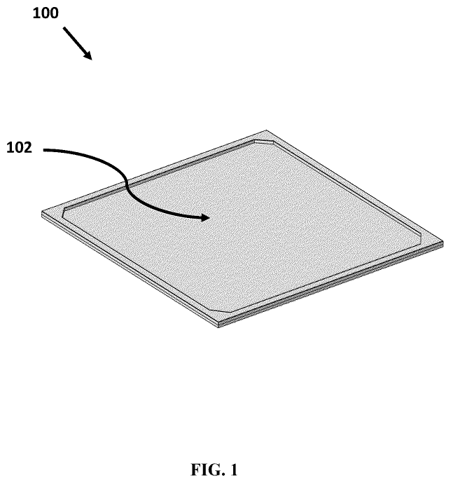

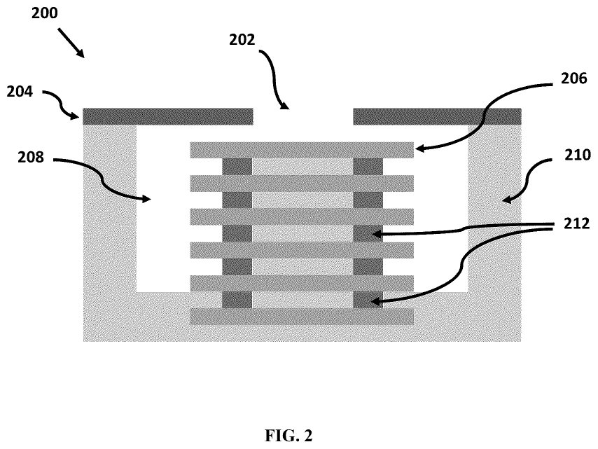

FIG. 1 shows a 3D view of a CMOS semiconductor pad 100 according to an implementation of the disclosure. In some implementations, pad 100 is a vHF resistant pad. Electronic circuits in ICs may be connected to the outside through a structure called a pad such as pad 100. In some implementations, one or more pads are located at one or more locations of an IC. In certain implementations, a pad is essentially a block of metal, typically using the top metal available in the CMOS process stack, with the passivation removed above. Usually it has more metals and vias underneath (e.g., a vHF etched pad 200 as shown in FIG. 2), to give it mechanical strength and/or consistency. The passivation window above the topmost metal used in the pad is necessary to allow the electrical connection of wirebonding to the package or PCB, probe connection, or other means of connection like bumps and others.

FIG. 1 shows a 3D view of a CMOS semiconductor pad 100. Pad 100 may include multiple layers as shown in FIG. 2 from bottom to top, metal top, oxide and passivation. Pad 100 includes region 102 that may provide an electrical connection with the outside of an IC chip would happen via, for example, a wirebonding cable or a solder bump, and the like.

FIG. 2 shows cross-sectional view of a pad 200 according to an implementation of the disclosure. Pad 200 may be a vHF etched pad that include a top metal layer 206 and is forms by a stack of alternating metal layers and vias 212. The pad 200 may be formed below a passivation layer 204 having an opening and/or passivation window 202 that enables vHF etching of SiO₂ 210 to form a cavity 208 surrounding pad 200. One issue is that the vHF etches SiO₂ inside the pad 200. However, when vHF is applied to the wafer for a MEMS device and MEMS ESD protection device, the pad 200 is unfortunately etched also. That is a reason why a vHF resistant pad may be used. Overlapping of the SiN passivation layer over the top metal layer may be about 2.5 μm-25 μm. The oxide may include SiO₂ while the passivation layer may include SiN. Although a preferred implementation is in CMOS with an aluminum metal stack (typically above 130 nm nodes), implementations may be applied to other nodes and other semiconductor processes. Etching processes other than vHF may be used for the ESD protection devices and systems disclosed herein. Also, ESD protection devices may be built and/or fabricated using another completely different MEMS manufacturing process.

A MEMS device may be formed by applying a vHF (vapor HF) etch to the finished CMOS. Pad 200 may be adversely affected by the vHF etching so, in certain implementations, pad 200 may be configured as an vHF resistant pad. This etches away the SiO₂ 210 in between the metals in the MEMS area, where passivation window and/or opening 202 has been made to allow the vHF to reach its target. FIG. 2 shows the cross-section of pad 200 after vHF etching. One of ordinary skill would recognize that other designs of pad 200 in the metals and vias below the top metal layer 206 can be implemented.

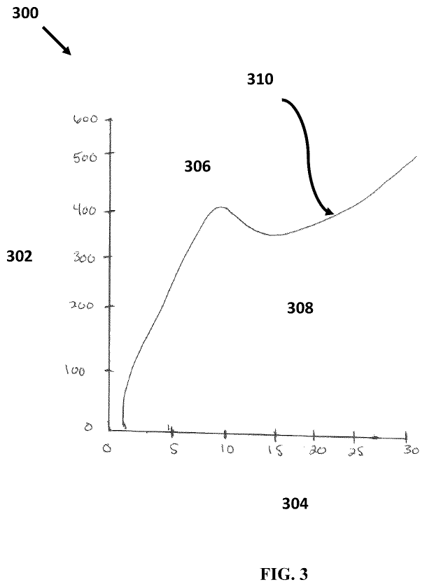

FIG. 3 shows a graph 300 of breakdown voltage magnitude 302 (volts) vs. contact gap size 304 (μm) for a ESD device according to an implementation of the disclosure. Graph 300 shows an arcing region 306 and no-arcing region 308 between Modified Paschen curve 310. ESD in ICs is the discharge of small amounts of electrical charge that acquire very high voltages and get in touch with the pads, e.g., pad 200, of the IC. Despite being a small amount of charge, the very high voltages involved, can easily damage the electrical circuit and/or IC or MEMS device thereof, resulting in an IC being a faulty device and/or not working anymore.

One technical concern is for certain types of sensors that may need to be in direct contact to the exterior of an IC package. For many sensors, like accelerometers, gyroscopes or magnetometers, this will be less of a concern, because they will not have direct access to the outside of the chip, and they will be connected only to the driving electronics. For other sensors like gas sensors, microphones, pressure sensors, ultrasound sensors, speaklets, digital sound reconstruction (DSR) devices, and so on, this can be a technical concern. More particularly there is concern for MEMS devices that are connected directly to IC pads because these pads, such as pad 200 and/or 402, may be very prone to receiving ESD. In particular, there is a substantial concern for RF DTCs, because for antenna tunning and aperture antenna applications, among others, the MEMS RF DTC will have to be connected to a pad as it will need to be connected directly to the antenna, at the system level printed circuit board (PCB).

While SiO₂ breakdown voltage is typically about 1 MV/mm, it has a much lower value of 3 kV/mm for air under normal conditions. For ICs with a MEMS device where there are gaps without SiO₂, when applying 1 kV under the human-body model (HBM) or any other ESD standard, there can be a spark in any gap of 300 μm or less. In practical terms, careful setup is needed when executing tests including proper positioning of the probes, e.g., spacing them apart between them as much as possible. Otherwise, there can be sparks between the probes because the pitch may be about 125 μm, and the distance from one edge of a pad to the other edge of the next pad may be about 240 μm.

While these breakdown voltages can be used down to gaps in the order of 15 μm, or smaller gaps, the so called Modified Paschen curve 310 may be used as illustrated in FIG. 3. Curve 310 illustrates that for small gaps, below an inflection point of about 10 μm to 15 μm, the breakdown voltage increases, because the number of air molecules found in such a tiny gap is very small. This means that the electrical field needed to create a spark increases, and it is no longer constant. However, if we keep reducing the gap, there is a point where electrons start leaving the electrode surface, which decreases again the breakdown voltage. That is, at these very small gaps, e.g., below 8 μm, we have sparks generated from the field emission of electrodes on the surface of the electrodes, and not due to the ionization of air molecules. The exact gap distance at which this happens depends on the chemical composition of the electrodes and/or their shape.

The chemical composition may be configured because the work function of the material indicates the energy each electrode needs to have, through the electrical field, in order to be detached from the electrode surface. The shape may also be configured because it determines the local electrical field at each point of the surface for a given voltage across the gap (between the electrodes).

Although down to about 150 nm CMOS nodes (depending on the fabrication process), and in particular, in the 180 nm node typically used to build RF DTC and other sensors, the metal lines are made with Al (and a small percentage of Cu), while the surface may be made of alumina, such as Al₂O₃. This is because aluminum oxidizes very quickly when in contact with the air, generating so called native oxide, which usually has a thickness of between 2 nm and 4 nm. This prevents further oxidation of the aluminum, which is useful for MEMS devices. But in terms of field emission, what matters is that the surface is made of alumina and hence there is a need to consider the work function of this oxide.

The following table shows the work function for some of the materials found in the back-end of a CMOS process.

TABLE 1
Work function for elements found
in the BEOL of a CMOS process.

| Material | Work function [eV] |
|---|---|
| Al | 4.06 to 4.26 |
| Al₂O₃ | 4.70 |
| W | 4.32 to 5.22 |
| Cu | 4.53 to 5.10 |

Although at the pad, e.g., pad 200, and probe level, we might be able to ignite a spark with 1 kV or higher voltages When making measurements, testers need to be careful with the probe positioning as there can be sparks due to air ionization, while the ESD design and potential sparks at the MEMS device can occur if we did not have the ESD protection that would occur mainly due to field emission.

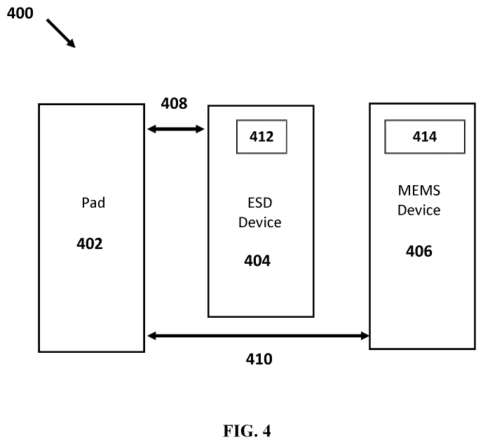

FIG. 4 shows a block diagram 400 of the distance between a pad 402 and ESD device 404 and the pad 402 and a MEMS device 406 according to some implementations of the disclosure. In some implementations, ESD device 404 is positioned within a device region of an IC such that spacing 408 is formed between pad 402 and ESD device 404. A MEMS device 406 is positioned within a device region of an IC such that spacing 410 is formed between pad 402 and MEMS device 406. As illustrated in FIG. 4, the distance, size, and/or magnitude of spacing 408 is less than the distance, size, and/or magnitude of spacing 410, which may ensure that if an IC and pad 402 are exposed to 1 kV or higher voltage caused by an electrostatic discharge, the ESD voltage will more likely be discharged by ESD device 404 via gap 412 to ground or another pad instead of being discharged by MEMS device 406 because gap 414 is larger than gap 412.

In other words, the smaller sized gap 412 within ESD device 404 facilitates earlier arcing across gap 412 and grounding of the ESD voltage before arcing can occur across gap 414 of MEMS device 406 which could damage MEMS device 406. In some implementations, ESD device 404 is positioned closer to pad 402 than MEMS device 406 to facilitate spacing 408 being smaller in size than spacing 410. In certain implementations, ESD device 404 is positioned between pad 402 and MEMS device 406, which ensures that the size of spacing 408 is less than the size of spacing 410, and also facilitates that ESD device 404 is within an electrical flow path generated by the ESD voltage. In some implementations, ESD device 404 includes gap 412 that facilitates ESD voltage discharge within ESD device 404. In such an implementation, ESD device is coupled electrically to pad 402 while gap 412 enables arcing via gap 412 based on a target ESD voltage setting. Gap 412 may be configured with a size that is smaller than the size of gap 414 within MEMS device 406. Gap 414 may be a gap between at least two elements of MEMS device 406. Hence, the smaller sized gap 412 is configured to enable arcing and grounding of an ESD via ESD device 404 instead of allowing possible damaging ESD via gap 414 of MEMS device 406.

In certain implementations, the relative location of the elements illustrated in FIG. 4 could be different. For instance, ESD device 404 could be located to the left of Pad 402, or somewhere else, as the illustrated layout is a 2D drawing. Although not illustrated in FIG. 4, various combination of the electrical path and impedance may be implemented regarding the relative position of the elements. Various implementations of ESD device 404 enable a spark to be generated ahead of within the MEMS device. It could be that for a given target voltage the spark is never generated in the MEMS device 406 and it was always generated in the ESD device 404. Or it could be that the MEMS device 408 could generate the spark, but it happens to be generated faster at the ESD device 404. To achieve this in certain implementations, the ESD design and location (close to the pad) needs to be such that for the ESD charge, it is easier to be discharged via a spark through the ESD device 404 than through the MEMS device 406. If we imagine the MEMS device 406 as having similar shape and gap than the ESD device 404, then in certain implementations the ESD device 404 is placed closer to the pad 402 than for the MEMS device 406. But if for instance the ESD device 404 has a shorter gap than all the gaps in the MEMS device 406, then it may the ESD device 406 may be positioned farther away from the pad 402 than the MEMS device 406 distance from the pad 402. In various implementations, the ESD device 406 is located closer to the pad 402 than the distance from the MEMS device 406 to the pad 402 anyway.

In order to facilitate the ESD discharge at the ESD device 404 instead of the MEMS device 406 in some implementations, a shorter gap at the ESD device 404 is implemented compared to the gaps at the MEMS device 406. In other implementations, the ESD device 404 is located closer to the pad 402. In further implementations, the gap is made smaller at the ESD device 404 when a desired threshold voltage to protect the MEMS device 406 is set. That is, the ESD protection device 404 can be configured in a way that our target protection voltage is equal to the pull-in voltage of the device. But it could be also a bit below it, just to make the gap shorter, which would then generate the spark. For example, it may be 5%, 10%, 15%, 20%, and so on lower. If it is set equal or above the pull-in voltage, then the gap will close to zero. Although this would usually produce microweldings, having an ESD discharge being limited and with a small amount of charge, microwelding may not happen necessarily. In some implementations, threshold voltages as low as 100V are used. That is the case of the RF DTC for instance.

In order to increase reliability of the ESD protection device 404, an array of ESD protection devices may be implemented and connected in parallel. In practice, all the current will usually flow through one of them. In case where the one with current flow gets damaged, the other ESD protection device will be available to protect the circuit and/or MEMS device when the next ESD discharges occur. An ESD event is not something that is meant to occur many times. In fact, for most systems it usually can happen only when assembling and soldering a device. Because most ICs are hidden inside the device, and hence to prone to the user touching their pads. So in many situations a ESD protection device that can survive a finite number of discharges would be of interest.

The option of an ESD protection device that can protect actively, by means of reducing the gap when a threshold voltage is applied could be implemented with a simple cantilever or bridge structure. Given the high pull-in voltages and small size (to minimize parasitic capacitance) needed, the preferred shape will be a bridge (clamped-clamped structure) rather than a cantilever (clamped on only one side). In various implementations, the bridge is designed so that it is actuated either in plan or out of plane.

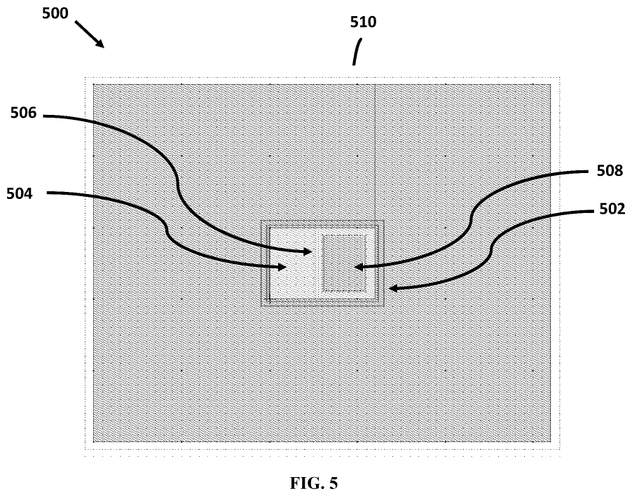

FIG. 5 shows a layout view of a proof-of-concept integrated circuit 500 including an ESD device 502 according to an implementation of the disclosure. The example implementation of FIG. 5 includes a bridge 506 that will move in-plane, towards the block 508 located to its right when a high voltage is found between the bridge 506 and the block 508. The metal block 508 goes down to a lower metal plan 504, which is connected to the ground. The bridge 506 is connected to a pad. ESD discharge device 502 may include a very narrow gap of 300 nm in between bridge 506 and block 508.

ESD discharge device 502 may include an electrostatic discharger 510 may be a passive device or active device. In the example of FIG. 5, an electrostatic discharger 510 includes at least bridge 506 and block 508 that function as an active device and/or switch to facilitate discharge of an excessive ESD voltage. As a passive device, discharger 510 may include a block and/or stack including an electrically conductive material. The material may include, without limitation, Al, Cu, W, and Al₂O₃. Discharger 510 may provide a discharge path to ground when an ESD voltage between bridge 506 and block 508 exceeds a breakdown voltage set by the narrow gap. In various implementations, bridge 506 is connected to a pad such as pad 102 or 402, to facilitate discharge of an ESD voltage to ground. Although not shown, circuit 500 may include a MEMS device, while ESD device 502 is positioned closer to a pad to facilitate ESD protection of the MEMS device. Discharger 510 may include a plurality of nodes stacked vertical corresponding to metal layers stacked vertically in a corresponding pad such that at least one node and its corresponding metal layer of the pad form a gap being sized differently than the narrow gap.

Discharger 510 may be an active device such as a switch configured to discharge the excessive voltage when activated. The switch may have a fast response time and high pull-in voltage. The switch may be a protection device that has one or more springs that are closed by electrostatic actuation when there is an ESD discharge, and would end up having a very small gap. That is, upon closing the electrostatic switch, because of the native oxide at the Al layers, there would be no ohmic contact. However, the gap in various implementations would be very small, and hence discharge could occur.

The limit of this approach may be caused by the roughness of the metal walls or surfaces (depending on whether in-plane or out-of-plane actuation is used). In some implementations, a relatively large surface to emit electrons is used. Otherwise, if the roughness results in a gap that is too large, then only on those points at the end of the valleys caused by the roughness, there will be a small enough gap to generate field emissions. This could then concentrate all the current at those points, causing micro-weldings that would damage the device and probably the MEMS that it was intending to protect, which could end up short-circuited. A variant to this approach would be to design a lower actuation voltage device, that is actuated electrostatically during the IC test, and left closed (by means of microwelding, or some other mechanism). Or this could happen when the device was operated for the first time in the field, since with a low pull-in voltage any small voltage would cause this closing.

In some implementations, a seal surrounds ESD device 502. The seal may encapsulate ESD device 502 in a gas having different pressures and inert gases like N₂ inside the cavity surrounding ESD device 502. In such implementations, ESD device 502 may not use air breakdown but field emission. Hence, the density and type of gas molecules inside the gap between the electrodes of the switch may have an effect on the amount of electrical current and the difficulty to produce a discharge spark, and hence it can affect the threshold voltage and the capability of ESD device 502 to clip the ESD voltage at a safe level.

An ESD protection device may be connected between two pads, or between the pad and the ground. In some implementations, an ESD protection device is connected to at least one pad.

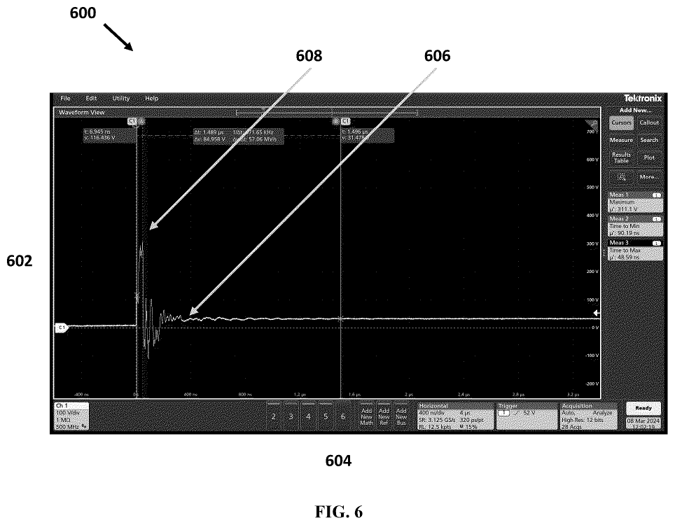

FIG. 6 shows a graph 600 of breakdown voltage 602 vs. time 604 when 1 kV is applied across a gap of 300 μm or less of an ESD device such as ESD device 502 according to an implementation of the disclosure. FIG. 6 shows the voltage capture with an oscilloscope when applying 1 kV with the ESD gun. As it can be seen the spark limits the voltage to 311V.

In an experimental setup for an RF DTCs, sparks were observed located at the start of the MEMS DTC, very near to the pads such as pad 200. In some tests, the ESD discharge was generated with a TESEQ NSG 438 ESD gun, applying 1 kV and the HBM network (150 pF and 330Ω) to the RF pads, and the voltage captured with a Tektronix MSO46 oscilloscope.

Two more captures were taken sequentially with the same device (not shown) with similar results. There is an important degree of variability from the gun, and probably also from the device, but the peak voltages were similar in magnitude: 311V, 315V and 309V.

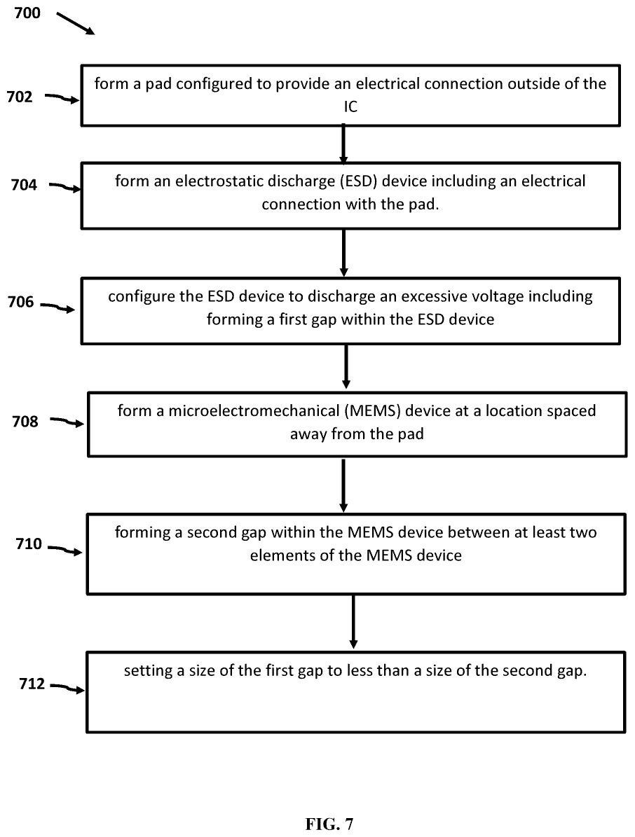

FIG. 7 shows a process 700 for fabricating an IC including an ESD device according to an implementation of the disclosure. Process 700 includes: forming a pad configured to provide an electrical connection outside of the IC (Step 702); forming an ESD device with an electrical connection to the pad (Step 704); configuring the ESD device to discharge an excessive voltage including forming a first gap within the ESD device (Step 706); forming a MEMS device at a location spaced away from the pad via a second gap (Step 708); forming a second gap within the MEMS device between at least two elements of the MEMS device (Step 710); and setting a size of the first gap to less than a size of the second gap (Step 712). As a CMOS or semiconductor process, some or all of the above process steps are performed concurrently.

In various implementations, an ESD protection device may be implemented for a MEMS device or an IC device (e.g., only ASIC and no MEMS). In some implementations, an ESD protection device as disclosed herein may be implemented to protect an external device, e.g., outside the chip. In certain implementations, an ESD protection system includes at least two pads and an ESD protection device. Although this one in principle it has less commercial interest. Hence, in some implementations, an ESD protection device is configured to protect devices at the PCB level, outside the chip. Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

1. An electrostatically-protected integrated circuit (IC) comprising:
a pad configured to provide an electrical connection to outside of the IC;
an electrostatic discharge (ESD) device being electrically coupled to the pad, the ESD device including a first gap configured to discharge an excessive voltage;
a microelectromechanical (MEMS) device including a second gap between at least two elements of the MEMS device; and
wherein a size of the first gap is less than a size of the second gap.

2. The integrated circuit of claim 1, wherein the first gap is sized to generate a spark at a target threshold voltage, the target threshold voltage being set to prevent the excessive voltage from reaching the MEMS device.

3. The integrated circuit of claim 2, wherein a shape of a portion of the ESD device at least partially determines the target threshold voltage.

4. The integrated circuit of claim 1, wherein the ESD device is spaced away from the pad by a first distance and the MEMS device is spaced away from the pad by a second distance, the first distance being less than the second distance.

5. The integrated circuit of claim 1, wherein the size of the first gap is less than or equal to one of 300 μm, 30 μm, 3 μm, and 300 nm.

6. The integrated circuit of claim 2, wherein the target threshold voltage is less than or equal to one of 1,000 volts, 400 volts, 350 volts, 325 volts, 315 volts, 250 volts, 200 volts, 150 volts, 125 volts, and 100 volts.

7. The integrated circuit of claim 1, wherein the ESD device includes a switch configured to discharge the excessive voltage when activated.

8. The integrated circuit of claim 1 comprising a seal surrounding the ESD device.

9. The integrated circuit of claim 1, wherein the seal encapsulates the ESD device in a gas.

10. The integrated circuit of claim 1 wherein the ESD device includes a plurality of nodes stacked vertical corresponding to metal layers stacked vertically in the pad, wherein at least one node and its corresponding metal layer of the pad form a third gap being sized differently than the first gap.

11. An electrostatic discharge (ESD) device comprising:
an electrostatic discharger being coupled electrically to a pad and forming a first gap, the electrostatic discharger being configured to discharge an excessive voltage received by the pad via the first gap;
wherein a size of the first gap determines the target threshold voltage at which the excessive voltage is discharged.

12. The ESD device of claim 11, wherein the size of the first gap is less than the size of a second gap formed between elements of a MEMS device.

13. The ESD device of claim 12, wherein a shape of a portion of the electrostatic discharger at least partially determines the target threshold voltage.

14. The ESD device of claim 13, wherein the shape is varied at least one of vertically and horizontally.

15. The ESD device of claim 11, wherein the size of the first gap is less than or equal to one of 300 μm, 30 μm, 3 μm, and 300 nm.

16. The ESD device of claim 12, wherein the target threshold voltage is less than or equal to one of 400 volts, 350 volts, 325 volts, 315 volts, 250 volts, 200 volts, 150 volts, 125 volts, and 100 volts.

17. The ESD device of claim 11, wherein the ESD device includes at least one of a bridge, cantilever, and a switch configured to discharge the excessive voltage when activated.

18. The ESD device of claim 11 comprising a seal surrounding the ESD device.

19. The ESD device of claim 11, wherein the seal encapsulates the ESD device in a gas.

20. An electrostatically-protected integrated circuit (IC) comprising:
a pad configured to provide an electrical connection to outside of the IC;
an electrostatic discharge (ESD) device being spaced away from the pad via a first spacing and configured to discharge an excessive voltage;
a microelectromechanical (MEMS) device being spaced away from the pad via a second spacing; and
wherein a distance of the first spacing is less than a distance of the second spacing.
